(19) United States
(12) Patent Application Publication
(10) Pub. No.: US 2025/0183014 A1
(43) Pub. Date: Jun. 5, 2025

(54) ELECTROSTATIC CHUCK AND PLASMA PROCESSING APPARATUS INCLUDING THE SAME

(71) Applicant: SEMES CO., LTD., Cheonan-si (KR)

(72) Inventors: Won Jun LEE, Cheonan-si (KR); Si Young JO, Cheonan-si (KR); Ji Yun JEON, Cheonan-si (KR); Ki Ryong LEE, Cheonan-si (KR); Soo Woong KIM, Cheonan-si (KR); Hee Yeon PARK, Cheonan-si (KR)

(73) Assignee: SEMES CO., LTD., Cheonan-si (KR)

(21) Appl. No.: 18/944,309

(22) Filed: Nov. 12, 2024

(30) Foreign Application Priority Data
Dec. 1, 2023 (KR) 10-2023-0172633

(51) Int. Cl. H01J 37/32

(52) U.S. Cl. CPC H01J 37/32724; H01J 2237/334

(57) ABSTRACT

Disclosed are an electrostatic chuck capable of precisely controlling the temperature of a peripheral area of a substrate and a plasma processing apparatus including the same. The electrostatic chuck configured to support a substrate in a plasma processing apparatus includes a metal base plate in which a coolant flow path formed and a ceramic puck bonded to an upper surface of the metal base plate. A bonded surface of the metal base plate has a protruding portion, and a bonded surface of the ceramic puck has a portion shaped corresponding to the protruding portion. The protruding portion is formed on a peripheral portion of the metal base plate so as to protrude farther upward than a central portion of the metal base plate. An outer coolant flow path adjacent to the protruding portion has an area expanding farther upward than a center-side coolant flow path located at the central portion.

### CROSS-REFERENCE TO THE RELATED APPLICATION

The present application claims priority to and the benefit of Korean Patent Application No. 10-2023-0172633, filed on Dec. 1, 2023, in the Korean Intellectual Property Office, the entire disclosure of which is incorporated herein by reference.

### BACKGROUND

### Technical Field

The present disclosure relates to an electrostatic chuck and a plasma processing apparatus including the electrostatic chuck.

### Description of the Related Art

A semiconductor manufacturing process is a process for manufacturing a semiconductor device on a substrate (e.g., a wafer), and includes, for example, photolithography, deposition, etching, ion implantation, and cleaning. In order to perform each manufacturing process, semiconductor manufacturing equipment that performs each process is provided in a clean room of a semiconductor manufacturing facility, and each process is performed on a substrate loaded in the semiconductor manufacturing equipment.

Processes using plasma, for example, etching and deposition, are widely used in the semiconductor manufacturing process. A plasma processing process is performed in such a manner that a substrate is seated at a lower portion in a plasma processing space, fluid for plasma processing is supplied, and voltage is applied by electrodes located at an upper portion and a lower portion in the plasma processing space.

In the plasma processing process, distribution of plasma and the reaction rate (e.g., etch rate) of a substrate are influenced by temperature. Therefore, it is important to maintain a uniform temperature over the entire area of the substrate in the plasma processing process. However, temperature control of a peripheral area of the substrate is more difficult than that of a central area of the substrate. Therefore, there is need for precise control of the temperature of the peripheral area of the substrate.

### SUMMARY

Therefore, the present disclosure has been made in view of the above problems, and it is an object of the present disclosure to provide an electrostatic chuck capable of precisely controlling the temperature of a peripheral area of a substrate and a plasma processing apparatus including the same.

The objects to be accomplished by the disclosure are not limited to the above-mentioned object, and other objects not mentioned herein will be clearly understood by those skilled in the art from the following description.

According to an embodiment of the present disclosure, an electrostatic chuck configured to support a substrate in a plasma processing apparatus includes a metal base plate in which a coolant flow path formed, and a ceramic puck bonded to an upper surface of the metal base plate. A surface of the metal base plate in contact with the ceramic puck has a protruding portion, and a surface of the ceramic puck in contact with the metal base plate has a portion shaped corresponding to the protruding portion. The protruding portion is formed on a peripheral portion of the metal base plate so as to protrude farther upward than a central portion of the metal base plate. The coolant flow path includes a center-side coolant flow path located at the central portion of the metal base plate and an outer coolant flow path located adjacent to the protruding portion, the outer coolant flow path having an area expanding farther upward than the center-side coolant flow path.

In the embodiment of the present disclosure, the metal base plate and the ceramic puck may be directly bonded to each other.

In the embodiment of the present disclosure, the metal base plate and the ceramic puck may be bonded to each other in a brazing or diffusion bonding manner.

In the embodiment of the present disclosure, the metal base plate may be made of a metal matrix composite having the same coefficient of thermal expansion as the material of the ceramic puck.

In the embodiment of the present disclosure, the top surface of the outer coolant flow path may be located at a position higher than the top surface of the center-side coolant flow path.

In the embodiment of the present disclosure, the top surface of the outer coolant flow path may be located at a position higher than a central portion of a contact surface between the metal base plate and the ceramic puck.

In the embodiment of the present disclosure, an oxide film may be formed on an outer side surface of the metal base plate.

In the embodiment of the present disclosure, the oxide film may be made of zirconium oxide (ZrO₂).

In the embodiment of the present disclosure, the oxide film may be formed on outer side surfaces of the metal base plate and the ceramic puck.

According to another embodiment of the present disclosure, an electrostatic chuck configured to support a substrate in a plasma processing apparatus includes a metal base plate made of a metal, the metal base plate in which a coolant flow path formed, and a ceramic puck bonded to an upper surface of the metal base plate. A surface of the metal base plate in contact with the ceramic puck has a protruding portion, and a surface of the ceramic puck in contact with the metal base plate has a portion shaped corresponding to the protruding portion. The protruding portion includes a center-side protruding portion formed at a position corresponding to central portions of the metal base plate and the ceramic puck and an outer protruding portion formed at a position corresponding to peripheral portions of the metal base plate and the ceramic puck. The coolant flow path includes a center-side coolant flow path located at a central portion of the metal base plate and an outer coolant flow path located adjacent to the outer protruding portion, the outer coolant flow path having an area expanding farther upward than the center-side coolant flow path.

According to still another embodiment of the present disclosure, a plasma processing apparatus includes an electrostatic chuck configured to support a substrate using electrostatic force and a coolant supply device configured to supply coolant to the electrostatic chuck. The electrostatic chuck includes a metal base plate in which a coolant flow path formed, a ceramic puck bonded to an upper surface of the metal base plate, and a coolant supply flow path configured to supply coolant to the coolant flow path.

A surface of the metal base plate in contact with the ceramic puck has a protruding portion, and a surface of the ceramic puck in contact with the metal base plate has a portion shaped corresponding to the protruding portion. The protruding portion is formed on a peripheral portion of the metal base plate so as to protrude farther upward than a central portion of the metal base plate.

The coolant flow path includes an outer coolant flow path formed in the metal base plate at a position adjacent to the protruding portion and a center-side coolant flow path formed in the metal base plate at a position farther inward than the outer coolant flow path.

The coolant supply flow path includes an outer coolant supply flow path connected to the outer coolant flow path and a center-side coolant supply flow path connected to the center-side coolant flow path.

The coolant supply device includes a coolant source configured to store coolant to be supplied to the outer coolant supply flow path and the center-side coolant supply flow path and a flow rate controller configured to individually control the flow rate of coolant supplied to each of the outer coolant supply flow path and the center-side coolant supply flow path.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIG. 1 shows a plasma processing apparatus in which a protruding portion is formed on a peripheral portion of a surface of a metal base plate that is bonded to a surface of a ceramic puck;

FIG. 2 shows a plasma processing apparatus in which a protruding portion is formed on a peripheral portion of a surface of a metal base plate that is bonded to a surface of a ceramic puck and an oxide film is formed on an outer side surface of the metal base plate;

FIG. 3 shows a plasma processing apparatus in which a protruding portion is formed on a peripheral portion of a surface of a metal base plate that is bonded to a surface of a ceramic puck and an oxide film is formed on outer side surfaces of the metal base plate and the ceramic puck;

FIG. 4 shows a plasma processing apparatus in which protruding portions are formed on a surface of a metal base plate that is bonded to a surface of a ceramic puck;

FIG. 5 shows a plasma processing apparatus in which protruding portions are formed on a surface of a metal base plate that is bonded to a surface of a ceramic puck and an oxide film is formed on an outer side surface of the metal base plate; and

FIG. 6 shows a plasma processing apparatus in which protruding portions are formed on a surface of a metal base plate that is bonded to a surface of a ceramic puck and an oxide film is formed on outer side surfaces of the metal base plate and the ceramic puck.

### DETAILED DESCRIPTION OF EXEMPLARY EMBODIMENTS

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

Parts irrelevant to description of the present disclosure will be omitted to clearly describe the present disclosure, and the same or similar constituent elements will be denoted by the same reference numerals throughout the specification.

In addition, constituent elements having the same configurations in several embodiments will be assigned with the same reference numerals and described only in the representative embodiment, and only constituent elements different from those of the representative embodiment will be described in the other embodiments.

Throughout the specification, when a constituent element is said to be “connected”, “coupled”, or “joined” to another constituent element, the constituent element and the other constituent element may be “directly connected”, “directly coupled”, or “directly joined” to each other, or may be “indirectly connected”, “indirectly coupled”, or “indirectly joined” to each other with one or more intervening elements interposed therebetween. In addition, throughout the specification, when a constituent element is referred to as “comprising”, “including”, or “having” another constituent element, the constituent element should not be understood as excluding other elements, so long as there is no special conflicting description, and the constituent element may include at least one other element.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

The present disclosure relates to an electrostatic chuck 10 and a plasma processing apparatus 1 including the electrostatic chuck 10, and more particularly, to an electrostatic chuck 10 for supporting a substrate W in the plasma processing apparatus 1 and a structure thereof capable of precisely controlling the temperature of a peripheral area of the substrate W.

The plasma processing apparatus 1 is equipment for performing plasma processing (e.g., dry etching) on the substrate W. When the substrate W is loaded in the plasma processing apparatus 1, radio frequency (RF) power is applied to an upper electrode and a lower electrode to generate an electromagnetic field, and a process gas supplied to the substrate W transitions to a plasma state due to the electromagnetic field, and reacts with a specific material of the substrate W. The substrate W having undergone plasma processing for a certain period of time is transferred to the outside of the plasma processing apparatus 1, and subsequent processing processes are performed.

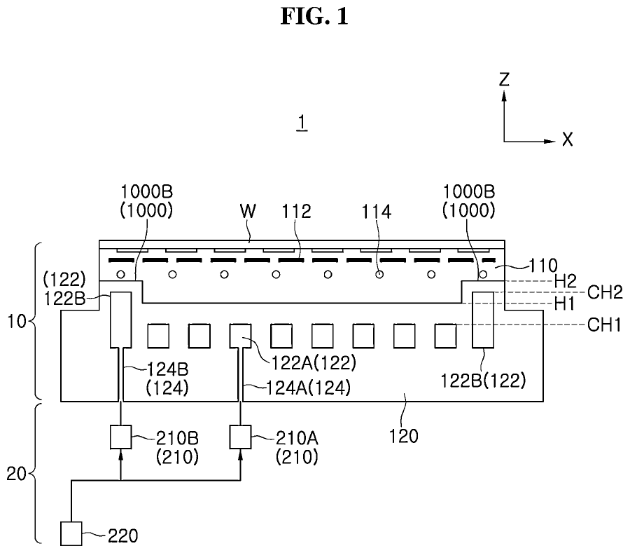

FIG. 1 is a view showing a plasma processing apparatus 1 according to the present disclosure. Referring to FIG. 1, the plasma processing apparatus 1 includes an electrostatic chuck 10 configured to support a substrate using electrostatic force and a coolant supply device 20 configured to supply coolant to the electrostatic chuck 10.

The electrostatic chuck 10 includes a metal base plate 120 having a coolant flow path 122 formed therein, a ceramic puck 110 bonded to an upper portion of the metal base plate 120, and a coolant supply flow path 124 configured to supply coolant to the coolant flow path 122.

A surface of the metal base plate 120 that is in contact with the ceramic puck 110 has a protruding portion 1000, and a surface of the ceramic puck 110 that is in contact with the metal base plate 120 has a portion shaped corresponding to the protruding portion 1000. The protruding portion 1000 is formed on a peripheral portion of the metal base plate 120 so as to protrude farther upward than a central portion of the metal base plate 120. Referring to FIG. 1, a peripheral portion of a surface of the metal base plate 120 that is bonded to a surface of the ceramic puck 110 protrudes upward. As shown in FIG. 1, the two bonded surfaces are not flat, and a portion thereof protrudes, which is referred to as a “protruding portion”. The metal base plate 120 and the ceramic puck 110 may have a structure in which the bonded surfaces thereof are not flat, i.e., the heights of the bonded surfaces are not uniform (uneven structure). In a case in which the protruding portion 1000 is formed as shown in FIG. 1, the metal base plate 120 and the ceramic puck 110 are easily aligned with each other when directly bonded to each other. In addition, a bonding area between the metal base plate 120 and the ceramic puck 110 is increased, and accordingly, it is possible to ensure sufficient bonding strength therebetween.

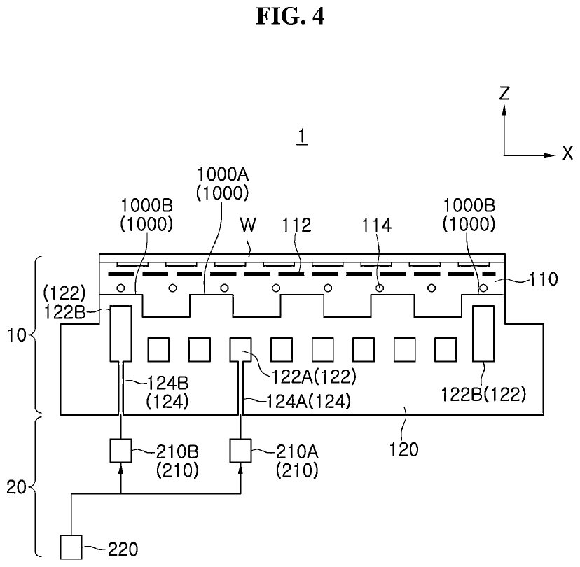

Although FIG. 1 shows a case in which the protruding portion 1000 is formed only on the peripheral portion of the metal base plate 120, an uneven structure may also be applied to the central portion of the metal base plate 120. FIGS. 1 to 3 show cases in which an outer protruding portion 1000B is formed on the peripheral portion of the metal base plate 120. FIGS. 4 to 6 show cases in which a central protruding portion 1000A is formed on the central portion of the metal base plate 120 and an outer protruding portion 1000B is formed on the peripheral portion of the metal base plate 120. Referring to FIG. 1, the protruding height H2 of the outer protruding portion 1000B is greater than the height H1 of the central portion of the surface of the metal base plate 120 that is bonded to the surface of the ceramic puck 110.

The metal base plate 120 and the ceramic puck 110 are directly bonded to each other. The metal base plate 120 and the ceramic puck 110 may be bonded to each other in a brazing or diffusion bonding manner. In general, the metal base plate 120 and the ceramic puck 110 are bonded to each other with a bonding layer interposed therebetween. In a case in which a bonding layer is provided, the bonding layer may be damaged by plasma. In order to prevent the bonding layer from being damaged by plasma, a ring-shaped sealing member is disposed on an outer side of the bonding layer. However, because the bonding layer is highly likely to be damaged despite provision of the sealing member, continuous maintenance is required for the bonding layer, which deteriorates the operability of the plasma processing apparatus 1. Therefore, the present disclosure proposes a structure for directly bonding the metal base plate 120 and the ceramic puck 110 to each other without a bonding layer. According to the present disclosure, the above-described uneven structure, i.e., the protruding portion 1000, may be employed so that the bonded surface of the metal base plate 120 and the bonded surface of the ceramic puck 110 are stably and tightly bonded to each other.

The metal base plate 120 may be made of a metal matrix composite having the same coefficient of thermal expansion as the material of the ceramic puck 110. In the present disclosure in which the metal base plate 120 and the ceramic puck 110 are directly bonded to each other, if the materials of the metal base plate 120 and the ceramic puck 110 have different coefficients of thermal expansion, bonding strength between the bonded surfaces thereof may be weakened. Therefore, the metal base plate 120 is made of a metal matrix composite processed to have the same coefficient of thermal expansion as the material of the ceramic puck 110, rather than being made of commonly used aluminum (Al). Accordingly, it is possible to ensure sufficient bonding strength between the bonded surfaces of the metal base plate 120 and the ceramic puck 110 in spite of various temperature changes in the plasma processing apparatus 1.

Referring to FIG. 1, an outer coolant flow path 122B adjacent to the protruding portion 1000 has an area extending farther upward than a center-side coolant flow path 122A located at the central portion of the metal base plate 120. The outer coolant flow path 122B is a coolant flow path formed inside the outer protruding portion 1000B. The outer coolant flow path 122B may extend upward in the region expanded upward by the outer protruding portion 1000B. That is, a top surface CH2 of the outer coolant flow path 122B may be located at a position higher than a top surface CH1 of the center-side coolant flow path 122A. The top surface CH2 of the outer coolant flow path 122B may be located at a position higher than the central portion (refer to H1) of the contact surface between the metal base plate 120 and the ceramic puck 110. Although not shown in detail in the drawings, a sensor for measuring the temperature of the substrate W may be provided at the outer protruding portion 1000B, thereby more accurately measuring the temperature of the peripheral portion of the substrate W.

The coolant flow path 122 includes an outer coolant flow path 122B formed in the metal base plate 120 at a position adjacent to the protruding portion 1000 and a center-side coolant flow path 122A formed in the metal base plate 120 at a position farther inward than the outer coolant flow path 122B, i.e., a position adjacent to the central portion of the metal base plate 120.

The coolant supply flow path 124 includes an outer coolant supply flow path 124B connected to the outer coolant flow path 122B and a center-side coolant supply flow path 124A connected to the center-side coolant flow path 122A.

The coolant supply device 20 supplies coolant to the coolant flow path 122 formed in the electrostatic chuck 10. The coolant supply device 20 includes a coolant source 210 configured to store coolant to be supplied to the outer coolant supply flow path 124B and the center-side coolant supply flow path 122A and a flow rate controller 220 configured to individually control the flow rate of coolant supplied to each of the outer coolant supply flow path 124B and the center-side coolant supply flow path 122A.

The coolant source 210 includes an outer coolant source 210B connected to the outer coolant supply flow path 124B and a center-side coolant source 210A connected to the center-side coolant supply flow path 124A. The outer coolant source 210B and the center-side coolant source 210A may store different types of coolants. Because the types of coolants supplied to the center-side coolant flow path 122A and the outer coolant flow path 122B are different from each other, the temperature control characteristics may be managed differently between the central portion and the peripheral portion of the electrostatic chuck 10.

The coolant source 210 may temporarily store coolant supplied from the outside, and may supply the coolant at a set flow rate (pressure). The outer coolant source 210B and the center-side coolant source 210A of the coolant source 210 may be implemented as a single integral tank, or may be provided separately from each other. A flow rate control valve configured to allow or interrupt the supply of coolant and to control the flow rate of the coolant may be provided on a flow path between the coolant source 210 and the coolant supply flow path 124. The flow rate controller 220 may control the flow rate of the coolant supplied from the coolant source 210 to the coolant supply flow path 124 through the flow rate control valve.

The flow rate controller 220 may perform control such that the flow rates of the coolant supplied to the outer coolant supply flow path 124B and the center-side coolant supply flow path 122A differ from each other. For example, when rapid cooling is required for the peripheral portion of the substrate W, the flow rate controller 220 may perform control such that the flow rate of the coolant supplied to the outer coolant supply flow path 124B is greater than the flow rate of the coolant supplied to the center-side coolant supply flow path 122A.

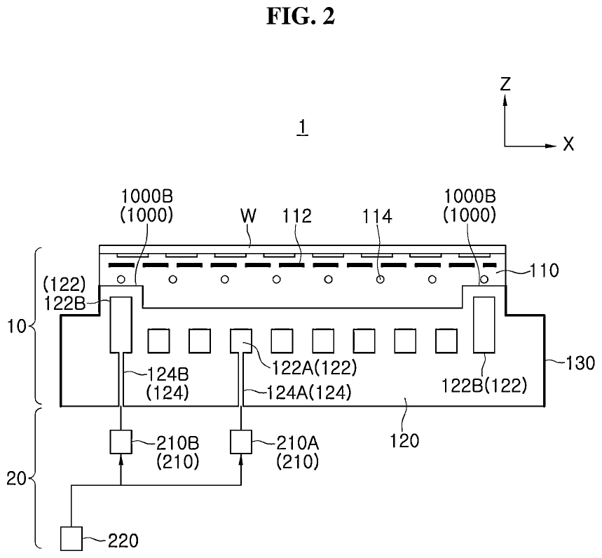

FIG. 2 shows a plasma processing apparatus 1 in which a protruding portion 1000 is formed on a peripheral portion of a surface of the metal base plate 120 that is bonded to a surface of the ceramic puck 110 and an oxide film 130 is formed on an outer side surface of the metal base plate 120. Referring to FIG. 2, the oxide film 130 is formed on the outer side surface of the metal base plate 120. The oxide film 130 is made of zirconium oxide (ZrO₂). Alumina (Al₂O₃), which is commonly used, has thermal conductivity of 32 W/mK and enables rapid heat exchange. However, high thermal conductivity causes external heat to be transferred to the electrostatic chuck 10, making it difficult to control the temperature of the electrostatic chuck 10. According to the present disclosure, because zirconium oxide (ZrO₂) has thermal conductivity of 2 W/mK, the oxide film 130 has a low heat exchange rate with the outside, thereby maintaining the temperature of the electrostatic chuck 10 at a constant level. By virtue of the oxide film 130 made of zirconium oxide (ZrO₂), it is possible to precisely control the temperature of the peripheral portion of the substrate W. The oxide film 130 prevents the metal base plate 120, which is a metallic material, from being etched by plasma.

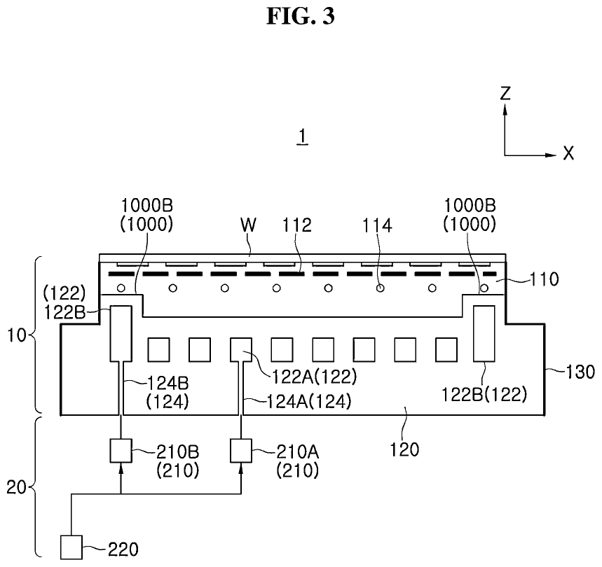

FIG. 3 shows a plasma processing apparatus 1 in which a protruding portion 1000 is formed on a peripheral portion of a surface of the metal base plate 120 that is bonded to a surface of the ceramic puck 110 and an oxide film 130 is formed on outer side surfaces of the metal base plate 120 and the ceramic puck 110. The oxide film 130 may be formed on the outer side surfaces of the metal base plate 120 and the ceramic puck 110. Compared to the configuration shown in FIG. 2, the oxide film 130 extends so as to be disposed on the outer side surface of the ceramic puck 110 as well as the outer side surface of the metal base plate 120. The oxide film 130 is made of zirconium oxide (ZrO₂). Because the oxide film 130 is formed on the outer side surface of the ceramic puck 110 as well as the outer side surface of the metal base plate 120, the strength of the bonded surface between the metal base plate 120 and the ceramic puck 110 may be increased. In the case in which the metal base plate 120 and the ceramic puck 110 are directly bonded to each other, the bonding strength at the peripheral area of the bonded surface may be low. However, the oxide film 130 may increase the bonding strength at the peripheral area of the bonded surface.

FIG. 4 shows a plasma processing apparatus 1 in which protruding portions 1000 are formed on a surface of the metal base plate 120 that is bonded to a surface of the ceramic puck 110. Compared to the configuration shown in FIG. 1, the protruding portions 1000 are formed on the central portion of the metal base plate 120 as well as the peripheral portion of the metal base plate 120. That is, the protruding portions 1000 include a center-side protruding portion 1000A formed at a position corresponding to the central portions of the metal base plate 120 and the ceramic puck 110 and an outer protruding portion 1000B formed at a position corresponding to the peripheral portions of the metal base plate 120 and the ceramic puck 110. In the metal base plate 120, an outer coolant flow path 122B adjacent to the outer protruding portion 1000B has an area extending farther upward than a center-side coolant flow path 122A located at the central portion of the metal base plate 120.

As shown in FIG. 4, in the case in which the uneven structure is applied to the entire areas of the bonded surfaces of the metal base plate 120 and the ceramic puck 110, the metal base plate 120 and the ceramic puck 110 are easily aligned with each other when directly bonded to each other. In addition, a bonding area between the metal base plate 120 and the ceramic puck 110 is increased, and accordingly, it is possible to ensure sufficient bonding strength therebetween.

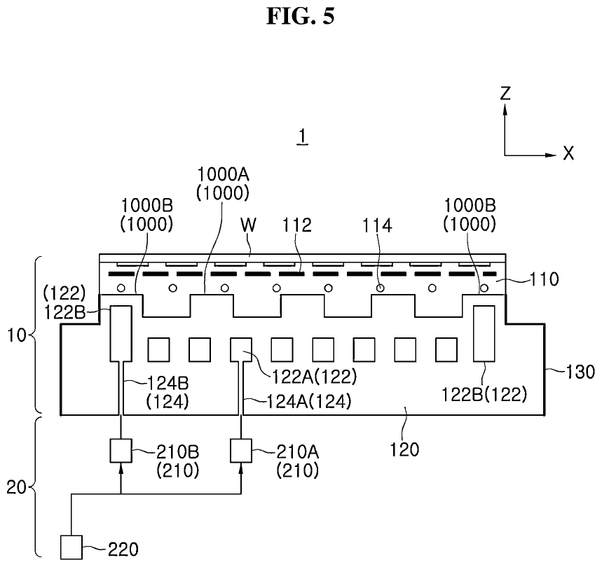

FIG. 5 shows a plasma processing apparatus 1 in which protruding portions 1000 are formed on a surface of the metal base plate 120 that is bonded to a surface of the ceramic puck 110 and an oxide film 130 is formed on an outer side surface of the metal base plate 120. Compared to the configuration shown in FIG. 4, the oxide film 130 is formed on the outer side surface of the metal base plate 120. The oxide film 130 is made of zirconium oxide (ZrO₂). By virtue of the oxide film 130 made of zirconium oxide (ZrO₂), it is possible to precisely control the temperature of the peripheral portion of the substrate W. The oxide film 130 prevents the metal base plate 120, which is a metallic material, from being etched by plasma.

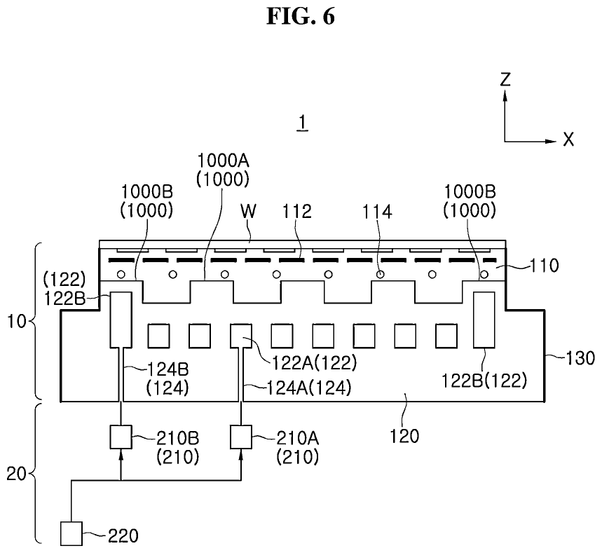

FIG. 6 shows a plasma processing apparatus 1 in which protruding portions 1000 are formed on a surface of the metal base plate 120 that is bonded to a surface of the ceramic puck 110 and an oxide film 130 is formed on outer side surfaces of the metal base plate 120 and the ceramic puck 110. Compared to the configuration shown in FIG. 5, the oxide film 130 extends so as to be disposed on the outer side surface of the ceramic puck 110 as well as the outer side surface of the metal base plate 120. The oxide film 130 is made of zirconium oxide (ZrO₂). Because the oxide film 130 is formed on the outer side surface of the ceramic puck 110 as well as the outer side surface of the metal base plate 120, the strength of the bonded surface between the metal base plate 120 and the ceramic puck 110 may be increased. In the case in which the metal base plate 120 and the ceramic puck 110 are directly bonded to each other, the bonding strength at the peripheral area of the bonded surface may be low. However, the oxide film 130 may increase the bonding strength at the peripheral area of the bonded surface.

As is apparent from the above description, according to the present disclosure, since an outer coolant flow path having an expanded area is formed adjacent to a protruding portion formed on a peripheral portion of a bonded surface between a ceramic puck and the metal base plate, it is possible to precisely control the temperature of a peripheral portion of a substrate.

The effects achievable through the disclosure are not limited to the above-mentioned effects, and other effects not mentioned herein will be clearly understood by those skilled in the art from this specification and the accompanying drawings.

Although the preferred embodiments of the present disclosure have been disclosed for illustrative purposes, those skilled in the art will appreciate that various modifications, additions and substitutions are possible, without departing from the scope and spirit of the disclosure.

The scope of the present disclosure should be defined only by the appended claims, and all technical ideas within the scope of equivalents to the claims should be construed as falling within the scope of the disclosure.

What is claimed is:

1. An electrostatic chuck configured to support a substrate in a plasma processing apparatus, the electrostatic chuck comprising:
a metal base plate in which a coolant flow path formed; and
a ceramic puck bonded to an upper surface of the metal base plate,
wherein a surface of the metal base plate in contact with the ceramic puck has a protruding portion, and a surface of the ceramic puck in contact with the metal base plate has a portion shaped corresponding to the protruding portion,
wherein the protruding portion is formed on a peripheral portion of the metal base plate so as to protrude farther upward than a central portion of the metal base plate, and
wherein the coolant flow path comprises:
a center-side coolant flow path located at the central portion of the metal base plate; and
an outer coolant flow path located adjacent to the protruding portion, the outer coolant flow path having an area expanding farther upward than the center-side coolant flow path.

2. The electrostatic chuck as claimed in claim 1, wherein the metal base plate and the ceramic puck are directly bonded to each other.

3. The electrostatic chuck as claimed in claim 2, wherein the metal base plate and the ceramic puck are bonded to each other in a brazing or diffusion bonding manner.

4. The electrostatic chuck as claimed in claim 1, wherein the metal base plate is made of a metal matrix composite having the same coefficient of thermal expansion as a material of the ceramic puck.

5. The electrostatic chuck as claimed in claim 1, wherein a top surface of the outer coolant flow path is located at a position higher than a top surface of the center-side coolant flow path.

6. The electrostatic chuck as claimed in claim 1, wherein a top surface of the outer coolant flow path is located at a position higher than a central portion of a contact surface between the metal base plate and the ceramic puck.

7. The electrostatic chuck as claimed in claim 1, further comprising an oxide film formed on an outer side surface of the metal base plate.

8. The electrostatic chuck as claimed in claim 7, wherein the oxide film is made of zirconium oxide (ZrO₂).

9. The electrostatic chuck as claimed in claim 7, wherein the oxide film is formed on outer side surfaces of the metal base plate and the ceramic puck.

10. An electrostatic chuck configured to support a substrate in a plasma processing apparatus, the electrostatic chuck comprising:
a metal base plate in which a coolant flow path formed; and
a ceramic puck bonded to an upper surface of the metal base plate,
wherein a surface of the metal base plate in contact with the ceramic puck has a protruding portion, and a surface of the ceramic puck in contact with the metal base plate has a portion shaped corresponding to the protruding portion,
wherein the protruding portion comprises:
a center-side protruding portion formed at a position corresponding to central portions of the metal base plate and the ceramic puck; and
an outer protruding portion formed at a position corresponding to peripheral portions of the metal base plate and the ceramic puck, and
wherein the coolant flow path comprises:
a center-side coolant flow path located at a central portion of the metal base plate; and
an outer coolant flow path located adjacent to the outer protruding portion, the outer coolant flow path having an area expanding farther upward than the center-side coolant flow path.

11. The electrostatic chuck as claimed in claim 10, wherein the metal base plate and the ceramic puck are directly bonded to each other.

12. The electrostatic chuck as claimed in claim 11, wherein the metal base plate and the ceramic puck are bonded to each other in a brazing or diffusion bonding manner.

13. The electrostatic chuck as claimed in claim 11, wherein the metal base plate is made of a metal matrix composite having the same coefficient of thermal expansion as a material of the ceramic puck.

14. The electrostatic chuck as claimed in claim 11, wherein a top surface of the outer coolant flow path is located at a position higher than a top surface of the center-side coolant flow path.

15. The electrostatic chuck as claimed in claim 11, wherein a top surface of the outer coolant flow path is located at a position higher than a central portion of a contact surface between the metal base plate and the ceramic puck.

16. The electrostatic chuck as claimed in claim 11, further comprising an oxide film formed on an outer side surface of the metal base plate.

17. The electrostatic chuck as claimed in claim 16, wherein the oxide film is made of zirconium oxide (ZrO₂).

18. The electrostatic chuck as claimed in claim 16, wherein the oxide film is formed on outer side surfaces of the metal base plate and the ceramic puck.

19. A plasma processing apparatus comprising:
an electrostatic chuck configured to support a substrate using electrostatic force; and
a coolant supply device configured to supply coolant to the electrostatic chuck,
wherein the electrostatic chuck comprises:
a metal base plate in which a coolant flow path formed;
a ceramic puck bonded to an upper surface of the metal base plate; and
a coolant supply flow path configured to supply coolant to the coolant flow path,
wherein a surface of the metal base plate in contact with the ceramic puck has a protruding portion, and a surface of the ceramic puck in contact with the metal base plate has a portion shaped corresponding to the protruding portion,
wherein the protruding portion is formed on a peripheral portion of the metal base plate so as to protrude farther upward than a central portion of the metal base plate,
wherein the coolant flow path comprises:
an outer coolant flow path formed in the metal base plate at a position adjacent to the protruding portion; and
a center-side coolant flow path formed in the metal base plate at a position farther inward than the outer coolant flow path,
wherein the coolant supply flow path comprises:
an outer coolant supply flow path connected to the outer coolant flow path; and
a center-side coolant supply flow path connected to the center-side coolant flow path, and
wherein the coolant supply device comprises:
a coolant source configured to store coolant to be supplied to the outer coolant supply flow path and the center-side coolant supply flow path; and
a flow rate controller configured to individually control a flow rate of coolant supplied to each of the outer coolant supply flow path and the center-side coolant supply flow path.

20. The plasma processing apparatus as claimed in claim 19, wherein the coolant source comprises:
an outer coolant source connected to the outer coolant supply flow path; and
a center-side coolant source connected to the center-side coolant supply flow path, and
wherein the outer coolant source and the center-side coolant source store different types of coolants.
